(19) United States
(12) Patent Application Publication
(10) Pub. No.: US 2026/0323891 A1
(43) Pub. Date: Oct. 15, 2026

(54) COOLING APPARATUS FOR POWER MODULE

(71) Applicants: Hyundai Motor Company, Seoul (KR); Kia Corporation, Seoul (KR)

(72) Inventors: Sang Hun LEE, Hwaseong-Si (KR); Hyong Joon PARK, Hwaseong-Si (KR); Se Heun KWON, Hwaseong-Si (KR)

(73) Assignees: Hyundai Motor Company, Seoul (KR); Kia Corporation, Seoul (KR)

(21) Appl. No.: 19/408,688

(22) Filed: Dec. 4, 2025

(30) Foreign Application Priority Data
Apr. 10, 2025 (KR) 10-2025-0046991

(51) Int. Cl. H05K 7/20

(52) U.S. Cl. CPC H05K 7/20927

(57) ABSTRACT

A cooling apparatus for a power module, is configured to improve cooling performance by utilizing vertical turbulent flow of a cooling medium through a manifold cover and a fin plate, and to prevent deformation of the manifold cover and the fin plate during bonding of a power module by applying a reinforcing rib structure to the manifold cover and the fin plate, maintaining cooling performance and improving overall quality.

### CROSS-REFERENCE TO RELATED APPLICATION(S)

The present application is based on and claims priority under 35 U.S.C. 119 to Korean Patent Application No. 10-2025-0046991, filed on Apr. 10, 2025, in the Korean Intellectual Property Office, the disclosure of which is herein incorporated by reference in its entirety.

### BACKGROUND OF THE PRESENT DISCLOSURE

### FIELD OF THE PRESENT DISCLOSURE

The present disclosure relates to a cooling apparatus for a power module that cools a power module using a cooling medium.

### DESCRIPTION OF RELATED ART

A power module is applied to, for example, an electric vehicle, and controls high voltage and high current. Accordingly, the power module generates a large amount of heat and requires appropriate cooling to maintain performance and durability. To this end, the power module is cooled using a cooling medium, or the waste heat generated from the power module is utilized for, for example, heating in a mobility system.

For cooling the power module, a cooling apparatus is connected to one side of the power module, and a cooling medium is circulated through the cooling apparatus. However, in the case of the cooling apparatus, the cooling efficiency is low because a simple tube structure or fin structure, which is commonly used, is applied.

In particular, during the coupling of the power module to the cooling apparatus, the cooling apparatus may be deformed or damaged, and when the cooling apparatus becomes deformed, a cooling imbalance may arise, or cooling efficiency may be reduced.

The foregoing described as the background art is intended merely to aid in the understanding of the background of the present disclosure, and is not intended to mean that the present disclosure falls within the purview of the related art already known to those skilled in the art.

### BRIEF SUMMARY

The present disclosure provides a cooling apparatus for a power module, which is configured to improve cooling performance by utilizing vertical turbulent flow of a cooling medium through a manifold cover and a fin plate forming the cooling apparatus, and to maintain cooling performance and improve overall quality by preventing deformation of the cooling apparatus during bonding between the power module and the cooling apparatus.

The technical subjects pursued in the present disclosure may not be limited to the above-mentioned technical subjects, and other technical subjects which are not mentioned herein may be clearly understood from the following description by those skilled in the art to which the present disclosure pertains.

In view of the foregoing, a cooling apparatus for a power module in various aspects of the present disclosure, may include a manifold cover including an open surface and a closed surface and in which a cooling medium flows. At least one cooling channel portion and at least one rib portion are disposed in a longitudinal direction on the closed surface, each cooling channel portion includes at least one first channel opened to one side and at least one second channel opened to another side, and the rib portion is disposed on the closed surface to overlap or extend around each cooling channel portion. The cooling apparatus may further include a fin plate coupled to the open surface of the manifold cover and including a cooling portion corresponding to each cooling channel portion. The cooling portion includes a plurality of protrusion portions extending in a direction crossing the first channel and the second channel.

In various aspects of the present disclosure, the cooling apparatus may further include a power module corresponding to each of the cooling portions of the fin plate, and the cooling channel portion of the manifold cover and the cooling portion of the fin plate may be provided in the same number as the power modules.

In various aspects of the present disclosure, the manifold cover may include an inlet and an outlet disposed at opposite end portions thereof to allow flow of the cooling medium therethrough, and the cooling channel portion and the rib portion extend in the longitudinal direction between the inlet and the outlet.

In various aspects of the present disclosure, a plurality of cooling channel portions may be disposed to be spaced apart from each other in the longitudinal direction, and the rib portion may extend in the longitudinal direction to be connected to each cooling channel portion.

In various aspects of the present disclosure, the cooling channel portion may include a plurality of partitions disposed in a direction intersecting the longitudinal direction, a one-side connection portion connecting first end portions of at least two of the partitions, and an opposite-side connection portion connecting second end portions of at least two of the partitions, wherein the one-side connection portion and the opposite-side connection portion are alternately disposed at each of the partitions.

In various aspects of the present disclosure, the rib portion may be provided in the same number as the partitions.

In various aspects of the present disclosure, the one-side connection portion may be angled toward one side while being connected to the at least two partitions, and the angled end portion of the one-side connection portion may be disposed between the rib portions.

In various aspects of the present disclosure, the opposite-side connection portion may be angled toward the other side while being connected to the at least two partitions, and the angled end portion of the one-side connection portion may be disposed between the rib portions.

In various aspects of the present disclosure, the first channel and the second channel may be defined between respective partitions, and each of the partitions may be inclined relative to the longitudinal direction so that the width of the first channel gradually decreases from one side to the other side, the width of the second channel gradually increases from one side to the other side, and the partitions are alternately inclined in opposite directions.

In various aspects of the present disclosure, the rib portion may protrude from the closed surface of the manifold cover, and a cross-sectional shape of a protruding end portion of the rib portion may gradually decrease in the protruding direction thereof.

In various aspects of the present disclosure, the end portion of the rib portion may include a triangular or curved cross-section.

In various aspects of the present disclosure, the protrusion portions of the fin plate may extend in a direction orthogonal in a direction in which the rib portion extends, and the protrusion portions may be spaced apart from each other in the longitudinal direction of the fin plate.

In various aspects of the present disclosure, the protrusion portions may divided multiple times in the extending direction thereof.

In various aspects of the present disclosure, when a plurality of cooling channel portions are disposed, the protrusion portions may be divided to cover respective ones of the cooling channel portions.

In various aspects of the present disclosure, the protrusion portions may protrude from the fin plate, and the cross-sectional shape of protruding end portions of the protrusion portions may gradually decrease in the protruding direction thereof.

With the cooling apparatus for a power module of the present disclosure, cooling performance is improved by utilizing vertical turbulent flow of the cooling medium through the manifold cover and the fin plate.

Furthermore, by applying a reinforcing rib structure to the manifold cover and the fin plate, deformation of the manifold cover and the fin plate during bonding of the power module is prevented, maintaining cooling performance and improving overall quality.

Advantageous effects obtainable from the present disclosure may not be limited to the above-mentioned effects, and other effects which are not mentioned herein may be clearly understood from the following description by those skilled in the art to which the present disclosure pertains.

### BRIEF DESCRIPTION OF THE DRAWINGS

The above and other aspects, features, and advantages of the present disclosure will be more apparent from the following detailed description taken in conjunction with the accompanying drawings, in which:

FIG. 1 is a schematic view exemplarily illustrating a cooling apparatus for a power module according to an exemplary embodiment of the present disclosure;

FIG. 2 is a view exemplarily illustrating the cooling apparatus for a power module according to an exemplary embodiment of the present disclosure;

FIG. 3 is a plan view exemplarily illustrating a manifold cover according to an exemplary embodiment of the present disclosure;

FIG. 4 is a plan view exemplarily illustrating a fin plate according to an exemplary embodiment of the present disclosure;

FIG. 5 is a view exemplarily illustrating cooling channel portions and rib portions of a manifold cover according to an exemplary embodiment of the present disclosure;

FIG. 6 is a view exemplarily illustrating cooling portions of the fin plate according to an exemplary embodiment of the present disclosure;

FIG. 7 is a view exemplarily illustrating an exemplary embodiment of rib portions in the manifold cover according to an exemplary embodiment of the present disclosure; and

FIG. 8 is a view exemplarily illustrating another embodiment of the rib portions in the manifold cover according to an exemplary embodiment of the present disclosure.

### DETAILED DESCRIPTION

In describing the embodiments set forth herein, a detailed description of known functions or configurations incorporated herein will be omitted when it is determined that the description may make the subject matter of the embodiments set forth herein unclear. In addition, it should be appreciated that the accompanying drawings are provided only for the sake of easy understanding of the embodiments set forth herein, and the technical idea of the present disclosure is not limited to the accompanying drawings and includes all modifications, equivalents, or alternatives falling within the spirit and scope of the present disclosure. The following descriptions are not intended to limit the present disclosure to the described form or specific field, and it is considered that various alternative modifications and changes may be made to the present disclosure regardless of whether the descriptions are explicit or implicit. Those skilled in the art to which the present disclosure pertains will appreciate that the contents of the present disclosure may be changed in forms and details.

The present disclosure will be described with reference to embodiments. However, as understood by a person ordinarily skilled in the art to which the present disclosure belongs, the various aspects included herein may be modified or otherwise implemented in different ways without departing from the spirit and scope of the present disclosure. Accordingly, the following description is to be considered exemplary, and is intended to teach those ordinarily skilled in the art to which the present disclosure belongs how to make and use various embodiments. It is to be understood that the forms of the present disclosure illustrated and described herein are exemplary embodiments. Equivalent elements, materials, processes, or steps may be substituted for those exemplified and described in the present disclosure. Expressions used in the present disclosure, such as “including,” “comprising,” “incorporating,” “consisting of,” “have,” or “is,” should be interpreted in a non-exclusive manner, i.e., to allow for the inclusion of items, components, or elements not explicitly listed. In addition, references to the singular form should be interpreted to include the plural form as well.

Furthermore, the various embodiments included herein should be regarded as exemplary and descriptive, and should not be construed as limiting the scope of the present disclosure. All references to joining (e.g., attached, affixed, coupled, and connected) are used solely to facilitate understanding of the present disclosure and are not intended to limit the position, orientation, or use of any component or method included herein. Accordingly, references to joining should be interpreted broadly. Moreover, these references to joining do not imply that two or more elements are directly connected to each other. Furthermore, all numerical terms, such as “first,” “second,” “third,” “primary,” “secondary,” “main,” or any other generic terms or numerical expressions, are to be understood solely as identifiers to aid in the understanding of the various components, embodiments, modifications, or variations of the present disclosure, and do not imply any limitations as to any component, embodiment, modification, variation, or their order or preference. That is, these terms may be used to describe various components but should not be construed as limiting the components to those terms. These terms are used only to distinguish one component from another.

The terms "module" and "unit" used for the elements in the following description are provided or interchangeably used in consideration of only the ease of writing the specification, and do not have distinct meanings or roles by themselves.

In the case where an element is referred to as being "connected" or "coupled" to any other elements, it should be understood that not only the element may be directly connected or coupled to the other elements, but also another element may exist therebetween. Contrarily, in the case where an element is referred to as being "directly connected" or "directly coupled" to any other element, it should be understood that no other element exists therebetween.

Any number or variety of components in any of the configurations described herein may be included within the scope of the present disclosure described herein. The components may include any combination of the features described herein and may be disposed in any of the various configurations described herein. The concepts related to the structure and arrangement of the components of the present disclosure, as well as their use and operation, may be applied to any number of embodiments in any combination, as well as to the specific embodiments discussed herein. Embodiments including those including various features in various arrangements are described below with reference to the drawings.

Hereinafter, various embodiments set forth herein will be described in detail with reference to the accompanying drawings, and the same or similar elements are provided the same and similar reference numerals regardless of figure numbers, so duplicate descriptions thereof will be omitted.

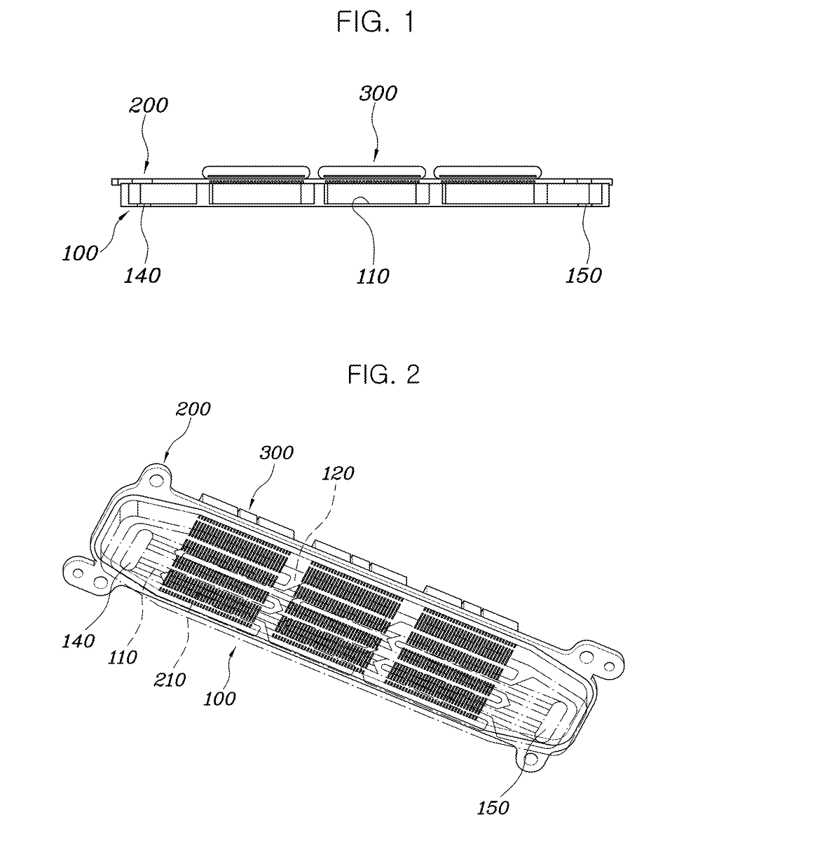

FIG. 1 is a schematic view exemplarily illustrating a cooling apparatus for a power module according to an exemplary embodiment of the present disclosure. FIG. 2 is a view exemplarily illustrating the cooling apparatus for a power module according to an exemplary embodiment of the present disclosure.

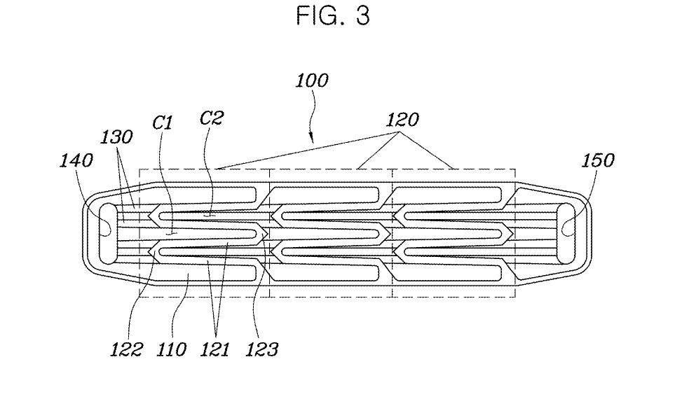

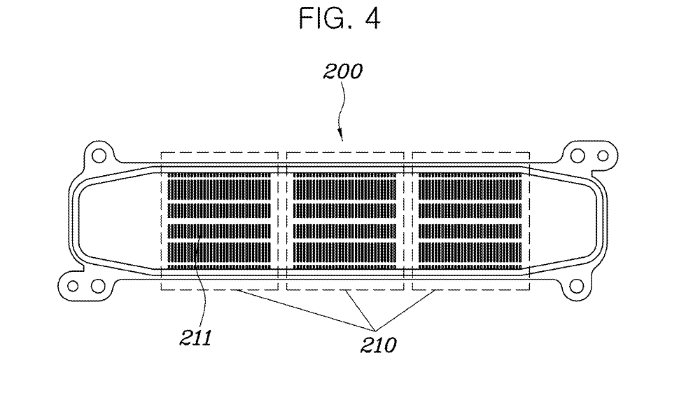

FIG. 3 is a plan view exemplarily illustrating a manifold cover 100 according to an exemplary embodiment of the present disclosure. FIG. 4 is a plan view exemplarily illustrating a fin plate 200 according to an exemplary embodiment of the present disclosure.

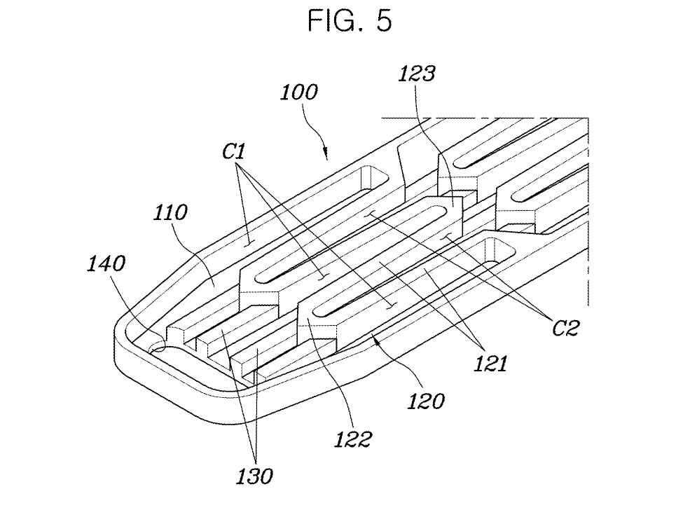

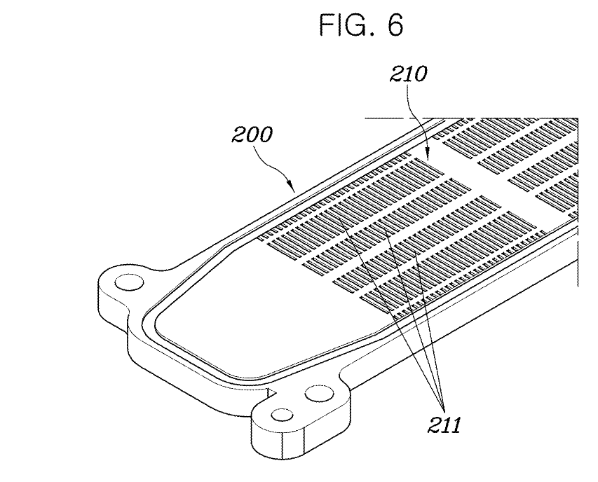

FIG. 5 is a view exemplarily illustrating a cooling channel portion 120 and a rib portion 130 of the manifold cover 100 according to an exemplary embodiment of the present disclosure. FIG. 6 is a view exemplarily illustrating a cooling portion 210 of the fin plate 200 according to an exemplary embodiment of the present disclosure.

The present disclosure relates to a manifold cover 100 and a fin plate 200 for cooling a power module 300. The manifold cover 100 and the fin plate 200 are bonded to each other and are configured to cool the power module 300 by allowing a cooling medium to flow therein.

The cooling medium may be air, cooling water, or a refrigerant, and may perform heat-exchange with the power module 300 while flowing inside the manifold cover 100 and the fin plate 200.

As illustrated in FIGS. 1-6, the cooling apparatus for a power module according to an exemplary embodiment of the present disclosure may include a manifold cover 100 including an open surface and a closed surface 110 and configured to allow a cooling medium to flow therein. At least one cooling channel portion 120 and at least one rib portion 130 are disposed in a longitudinal direction on the closed surface 110, each cooling channel portion 120 includes at least one first channel C1 opened to one side and at least one second channel C2 opened to the other side, and the rib portion 130 is disposed on the closed surface 110 to overlap or extend around each cooling channel portion 120. The cooling apparatus may further include a fin plate 200 coupled to the open surface of the manifold cover 100 and including a cooling portion 210 corresponding to each cooling channel portion 120. The cooling portion 210 includes a plurality of protrusion portions 211 extending in a direction crossing the first channel C1 and the second channel C2.

The power module 300 may be cooled by the manifold cover 100 and the fin plate 200, and the power module 300 may be bonded to correspond to the cooling portion 210 of the fin plate 200.

A plurality of power modules 300 may be bonded to an external surface of the fin plate 200 to be spaced apart from each other. In the present manner, the power modules 300 and the fin plate 200 may be thermally connected to allow heat generated from the power modules 300 to be cooled by the cooling medium via the fin plate 200.

In an exemplary embodiment of the present disclosure, the power module may include a switching element that generates heat. For example, the switching element is configured to perform ON/OFF control of power required to drive a motor, and may be at least one selected from a BJT, a silicon controlled rectifier (SCR), a TRIAC, a unijunction transistor (UJT), a programmable unijunction transistor (PUT), a junction field effect transistor (JFET), a gate turn-off thyristor (GTO), a MOS controlled thyristor (MCT), an injection-enhanced gate transistor (IEGT), an insulated gate bipolar transistor (IGBT), an integrated gate commutated thyristor (IGCT), MOSFET, an intelligent power device (IPD) (a semiconductor switch), and a diode device.

The manifold cover 100 may be manufactured through aluminum die casting or forging, or may be manufactured through plastic injection molding. Since the manifold cover 100 does not affect the cooling performance of the power modules 300, the manifold cover may be made of various materials that are less corrosive and that are configured for reducing weight. The manifold cover 100 includes an open surface and a closed surface 110, and the closed surface 110 may include a cooling channel portion 120 and a rib portion 130. The cooling channel portion 120 may include at least one first channel C1 opened to one side and at least one second channel C2 opened to the other side to allow a cooling medium to flow from the first channel C1 to the second channel C2 via the cooling portion 210 of the fin plate 200.

The fin plate 200 is configured to cover the open surface of the manifold cover 100, and may be bonded to the open surface of the manifold cover 100 by various methods such as welding, adhesion, or bolting. The fin plate 200 may be made of a material configured for heat transfer, including aluminum, to enable heat-exchange between the power modules 300 and the cooling medium. Furthermore, the fin plate 200 includes a cooling portion 210 corresponding to the cooling channel portion 120 of the manifold cover 100. The cooling portion 210 includes a plurality of protrusion portions 211 extending in a direction crossing the first channel C1 and the second channel C2 to allow a cooling medium introduced through the first channel C1 to flow to the second channel C2 through spaces among the plurality of protrusion portions 211.

As the cooling medium passes through the cooling channel portion 120 of the manifold cover 100 and the cooling portion 210 of the fin plate 200, an impingement jet cooling structure may be formed. Here, impingement jet cooling refers to a method of removing heat by directly spraying a cooling medium onto a localized point. To implement heat-exchange by the impingement jet cooling method, turbulent flow of the cooling medium needs to be utilized. That is, to actively implement the effects of the impingement jet cooling method, it is necessary to utilize turbulent flow rather than laminar flow. Here, turbulent flow refers to a flow that has velocity components in a direction perpendicular to the main flow direction, that is, an irregular and diffusive flow caused by three-dimensional vorticity in vertical and lateral directions rather than along the primary flow direction. When turbulent flow occurs around an object, the cooling area and mixing of the cooling medium increase, enhancing the cooling efficiency.

The cooling channel portion 120 of the manifold cover 100 includes the first channel C1 and the second channel C2, and the cooling portion 210 of the fin plate 200 includes a plurality of protrusion portions 211 connecting the channels to enable an impingement jet cooling method. This allows the cooling area to be optimized at a necessary localized portion, and enables proper mixing of the cooling medium, improving cooling efficiency.

Meanwhile, the manifold cover 100 of the present disclosure may further include a rib portion 130 in addition to the cooling channel portion 120. The rib portion 130 may be disposed on the closed surface 110 of the manifold cover 100 to overlap each cooling channel portion 120 or to extend around each cooling channel portion 120, dispersing stress concentration in the manifold cover 100 and reducing deformation.

Furthermore, the fin plate 200 may include a plurality of protrusion portions 211 forming the cooling portion 210 and extending in a direction crossing the first channel C1 and the second channel C2, guiding the fluid flow as well as increasing the fin plate’s own rigidity while dispersing stress concentration.

Accordingly, the rib portion 130 is disposed on the manifold cover 100 and the plurality of protrusion portions 211 are disposed on the fin plate 200 to ensure structural rigidity of each of the manifold cover and the fin plate, stabilizing the structure and preventing deformation due to thermal shock occurring during bonding of the power modules 300. That is, during bonding of the power modules 300, solder bonding may be performed, and thermal shock may be applied to the fin plate 200, which may cause thermal deformation in the manifold cover 100 or the fin plate 200. As described above, in an exemplary embodiment of the present disclosure, structural rigidity is ensured and thermal deformation is prevented by applying a support structure to the cooling channel portion 120 of the manifold cover 100 and the cooling portion 210 of the fin plate 200, which correspond to the portion where the power modules 300 are bonded.

The number of power modules 300 may be determined according to the specifications of an inverter, and the cooling channel portion 120 of the manifold cover 100 and the cooling portion 210 of the fin plate 200 may be disposed in the same number as the power modules 300. That is, the cooling channel portions 120 of the manifold cover 100 and the cooling portions 210 of the fin plate 200 may be disposed to correspond to the number and positions of the power modules 300 to cool the respective power modules 300, and the rib portions 130 of the manifold cover 100 and the protrusion portions 211 of the fin plate 200 may form a support structure to prevent thermal deformation which may occur during bonding of the power modules 300.

The manifold cover 100 includes an inlet 140 and an outlet 150 disposed at opposite end portions to allow flow of a cooling medium, and the cooling channel portions 120 and the rib portions 130 may extend in the longitudinal direction between the inlet 140 and the outlet 150.

In an exemplary embodiment of the present disclosure, the manifold cover 100 and the fin plate 200 may extend in a form of a straight line. This is merely an exemplary embodiment of the present disclosure, the manifold cover 100 and the fin plate 200 may have various shapes.

In the manifold cover 100 of the present disclosure, the inlet 140 and the outlet 150 are respectively disposed at opposite end portions, so that a cooling medium may be introduced through the inlet 140 and discharged through the outlet 150. Through this, the cooling medium may flow throughout the manifold cover 100 and the fin plate 200 and may perform heat-exchange with the plurality of power modules 300.

Furthermore, the cooling channel portion 120 and the rib portion 130 may extend in the longitudinal direction of the manifold cover 100 to guide the flow of the cooling medium and enhance the structural rigidity of the manifold cover 100 itself.

A plurality of cooling channel portions 120 may be disposed to be spaced apart from each other in the longitudinal direction, and the rib portion 130 may extend in the longitudinal direction to be connected to each of the cooling channel portions 120. The plurality of cooling channel portions 120 may be disposed to correspond to the plurality of power modules 300, and may be spaced at regular intervals to define sections in which impingement jet cooling is generated in conjunction with the cooling portions 210 of the fin plate 200. The rib portion 130 may extend in the longitudinal direction between the spaced cooling channel portions 120 to connect different ones of the cooling channel portions 120. The rib portion 130 may also be disposed in a direction intersecting the longitudinal direction to enhance the rigidity of the manifold cover 100. However, since the longitudinal direction of the manifold cover 100 corresponds to the flow direction of the cooling medium, the rib portion 130 may be disposed to extend in the longitudinal direction in consideration of the flow characteristics of the cooling medium. Furthermore, by connecting the plurality of cooling channel portions 120, the rib portion 130 may disperse stresses which may be locally generated in the cooling channel portions 120, improving the overall rigidity.

In more detail regarding the manifold cover 100, as illustrated in FIGS. 3 and 5, the cooling channel portions 120 extend in the longitudinal direction and each include a plurality of partitions 121 disposed in a direction intersecting the longitudinal direction, a one-side connection portion 122 connecting one end portions of at least two of the partitions 121, and an opposite-side connection portion 123 connecting other end portions of at least two of the partitions 121. The one-side connection portions 122 and the opposite-side connection portions 123 may be alternately disposed for the respective partitions 121.

The cooling channel portions 120 may each include partitions 121, a one-side connection portion 122, and an opposite-side connection portions 123, and may be disposed in a zig-zag pattern by alternately connecting the one-side connection portion 122 and the opposite-side connection portion 123 to the partitions 121 that are disposed in a direction intersecting the longitudinal direction thereof.

Among the plurality of partitions 121, the partitions 121 disposed at the outermost sides may be coupled to the edge portions of the manifold cover 100. The second channel C2 may be defined between the partitions 121 to which the one-side connection portion 122 is connected, and the first channel C1 may be defined between the partitions 121 to which the opposite-side connection portion 123 is connected. As a result, the cooling channel portion 120 may be configured so that the first channel C1 and the second channel C2 are disposed in an alternating pattern through the plurality of partitions 121, one-side connection portions 122, and opposite-side connection portions 123. In the present manner, the cooling channel portions 120 may define a plurality of first channels C1 and second channels C2 through the partitions 121, the one-side connection portions 122, and the opposite-side connection portions 123, and the protrusion portions 211 forming the cooling portion 210 of the fin plate 200 may extend to cross each of the partitions 121. Therefore, the cooling medium may flow from the first channels C1 to the second channels C2 through the gaps between the protrusion portions 211 and an impingement jet effect may be generated.

Meanwhile, the rib portion 130 may be disposed in the same number as the partitions 121. The rib portions 130 may extend in the longitudinal direction together with the partitions 121 and may be connected to the respective partitions 121 in the same number as the partitions 121 so that the partitions 121 of the cooling channel portion 120 extend to the rib portions 130. Therefore, even if stress concentration occurs in the partitions 121, the stress may be dispersed to the rib portions 130. Furthermore, as the rib portions 130 are connected to the respective partitions 121, a support structure may be disposed for each of the partitions 121. The rib portions 130 may extend in the longitudinal direction together with the partitions 121 to minimize interference with the flow of the cooling medium. Furthermore, each of the rib portions 130 may connect the respective cooling channel portions 120 and may extend from one end portion to the other end portion of the manifold cover 100 to enhance the overall structural rigidity. The rib portions 130 may have the same cross-sectional width to ensure moldability and facilitate stress dispersion.

Meanwhile, each of the one-side connection portions 122 may be angled toward one side while being connected to at least two of the partitions 121, and the angled end portion thereof may be disposed between the rib portions 130.

As illustrated in FIG. 5, the one-side connection portions 122 may each be connected to one end portions of at least two of the partitions 121 and may be angled toward one side thereof. As a result, the cooling medium flowing from one side to the other side may be dispersed by the angled portions of the one-side connection portions 122 and may smoothly flow into the first channels C1. Furthermore, as the angled end portions of the one-side connection portions 122 are each disposed between the rib portions 130, the cooling medium flowing between the rib portions 130 may also be dispersed by the angled portions of the one-side connection portions 122, allowing the cooling medium to smoothly flow into the first channels C1. Furthermore, each of the one-side connection portions 122 may be configured so that the angled end portion thereof is positioned at the center portion between the respective partitions 121 and between the rib portions 130, to prevent stress transmission through the partitions 121 from being excessively biased toward any one side and concentrated.

Meanwhile, each of the opposite-side connection portions 123 may be angled toward the other side while being connected to at least two of the partitions 121, and the angled end portion thereof may be disposed between the rib portions 130.

Each of the opposite-side connection portions 123 may be connected to the other end portions of at least two of the partitions 121 and may be angled toward the other side thereof. As a result, the cooling medium flowing from one side to the other side may be dispersed by the angled portions of the opposite-side connection portions 123 and may smoothly flow into the first channels C1 of the opposite-side cooling channel portions. Furthermore, each of the opposite-side connection portions 123 may be configured so that the angled end portion is disposed between the rib portions 130 and positioned at the center portion between the rib portions 130 to prevent stress transmission through the partitions 121 from being excessively biased toward any one side and concentrated. A portion of cooling medium may be guided to flow between the rib portions 130, improving the flowability of the cooling medium.

Meanwhile, in an exemplary embodiment of the present disclosure, the first channels C1 and the second channels C2 may be defined between the respective partitions 121. Each of the partitions 121 may be inclined in the longitudinal direction so that in the case of the first channels C1, the width gradually decreases from one side to the other side, and in the case of the second channels C2, the width gradually increases from one side to the other side thereof. The first channels C1 and the second channels C2 may be disposed alternately with opposite inclination directions.

Referring to FIG. 3, each of the partitions 121 may be inclined with respect to the longitudinal direction, and in each of the cooling channel portions 120, the partitions 121 may be alternately inclined in opposite directions, so that the shape of each channel may be disposed to gradually increase or decrease in area. In an exemplary embodiment of the present disclosure, in the case of the first channels C1, the area may gradually decrease from one side to the other side, and in the case of the second channels C2, the area may gradually increase from one side to the other side, which enables the flow rate and flow velocity of the cooling medium passing through the cooling portion 210 of the fin plate 200 to be evenly distributed across the entire channel, ensuring the cooling performance of the power module 300. The inclination angle of each of the partitions 121 may differ depending on each cooling channel portion 120, and may be variously adjusted depending on the cooling performance required for the power modules 300. That is, the first channels C1 and the second channels C2 may be configured to generate an axial flow contraction (vena contracta) due to the gradually increasing or decreasing channel area. In the first channels C1, the cooling medium may smoothly flow from the inlet side toward the far side due to the constricted flow path of the cooling medium. In the second channels C2, the flow rate of the cooling medium may gradually increase, allowing the cooling medium to be evenly distributed into the next cooling channel portion 120.

Meanwhile, the rib portions 130 may protrude from the closed surface 110 of the manifold cover 100, and a cross-sectional shape of protruding end portions of the rib portions 130 may gradually decrease in the protruding direction thereof.

The end portions of the rib portions 130 may include a polygonal shape such as a triangular shape or a curved shape in cross-section.

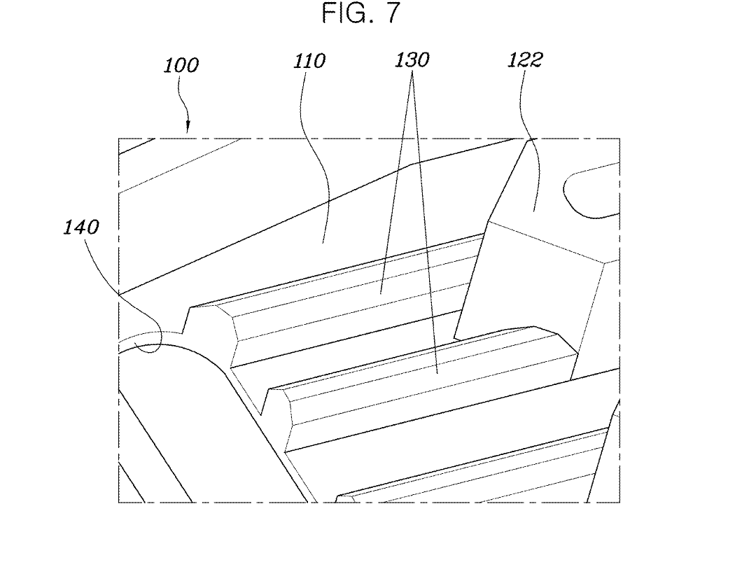

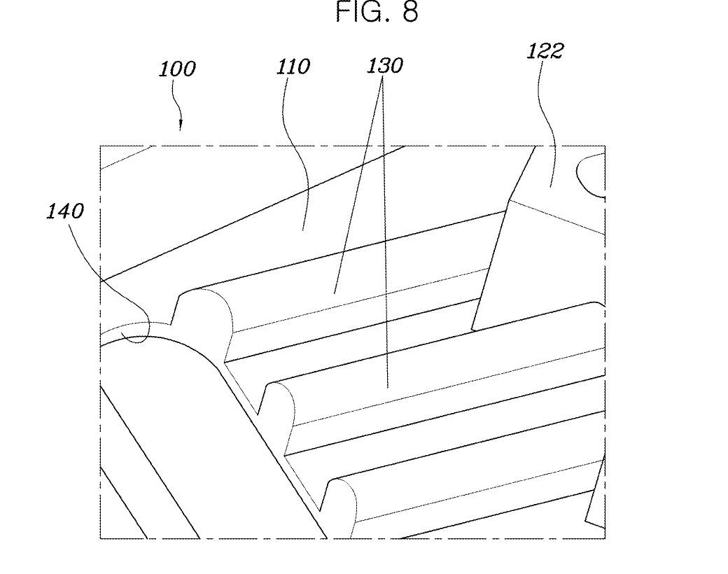

That is, as illustrated in FIG. 7, the cross section of the rib portions 130 may include a polygonal shape such as a triangular shape including a plurality of edge portions, or as illustrated in FIG. 8, the cross section of the rib portions 130 may include a semi-circular shape. The cross section of the rib portions 130 may have one of a right triangular shape, an isosceles triangular shape, or a semi-circular shape, but is not limited thereto. In the present way, the rib portions 130 may ensure overall rigidity while reducing interference with the flow of the cooling medium, as the cross-sectional shape thereof is chamfered or rounded to form a polygonal or circular shape.

In an exemplary embodiment of the present disclosure, the height of the rib portions 130 is lower than the height of the first channels C1 and the second channels C2.

Meanwhile, the protrusion portions 211 of the fin plate 200 may extend in a direction orthogonal to the direction in which the rib portions 130 extend, and may be spaced apart from each other in the longitudinal direction of the fin plate 200.

As illustrated in FIGS. 4 and 6, each of the cooling portions 210 of the fin plate 200 includes a plurality of protrusion portions 211, and each of the protrusion portions 211 extends in a direction orthogonal to the longitudinal direction in which the rib portions 130 extend, forming gaps between the protrusion portions 211 to allow the cooling medium to flow into portions in contact with the partitions 121 of the cooling channel portion 120. Furthermore, each of the protrusion portions 211 may be disposed in the longitudinal direction of the fin plate 200 to guide the flow of the cooling medium through the gaps between the protrusion portions 211.

Furthermore, the protrusion portions 211 may be divided multiple times in the extending direction in the present way, as each of the protrusion portions 211 is divided multiple times in the extending direction, it may be possible to avoid stress concentration on a specific portion, and to achieve structural stability against bending deformation. Here, each of the cooling portions 210 may be configured so that the extending length of each of the protrusion portions 211 is greater than the distance between the protrusion portions 211 in the extending direction thereof. Furthermore, the protrusion portions 211 may have different lengths depending on specific segments, so that the protrusion portions 211 correspond to the partitions 121 of a cooling channel portion 120 or locally provide enhanced rigidity in portions where structural strength is required.

Furthermore, when a plurality of cooling channel portions 120 are disposed, the protrusion portions 211 may be divided to cover the respective cooling channel portions 120. That is, the area of the cooling portions 210 defined by the protrusion portions 211 may be configured to cover the regions in which the cooling channel portions 120 are disposed, so that the cooling medium may form a flow path through gaps between the partitions 121 of the cooling channel portions 120 and the protrusion portions 211. Furthermore, the cooling channel portions 120 of the manifold cover 100 and the cooling portions 210 of the fin plate 200 may collectively form a support structure.

Meanwhile, the protrusion portions 211 may protrude from the fin plate 200, and the cross-sectional shape of the protruding end portions of the protrusion portions 211 may gradually decrease in the protruding direction. The end portions of the protrusion portions 211 may include a triangular or curved shape in cross-section.

The cross section of the protrusion portions 211 may have a polygonal shape including one of a right triangular shape, an isosceles triangular shape, or a semi-circular shape, but is not limited thereto. In the present way, the protrusion portions 211 may ensure overall rigidity while reducing interference with the flow of the cooling medium, as the cross-sectional shape thereof is chamfered or rounded to form a polygonal or circular shape.

With the cooling apparatus for a power module of the present disclosure, cooling performance is improved by utilizing vertical turbulent flow of the cooling medium through the manifold cover 100 and the fin plate 200.

Furthermore, by applying a reinforcing rib structure to the manifold cover 100 and the fin plate 200, deformation of the manifold cover 100 and the fin plate 200 during bonding of the power modules 300 may be prevented, maintaining cooling performance and improving overall quality.

Although the present disclosure has been described and illustrated in conjunction with various exemplary embodiments thereof, it will be apparent to those skilled in the art that various improvements and modifications may be made to the present disclosure without departing from the technical idea of the present disclosure defined by the appended claims.

What is claimed is:

1. A cooling apparatus for a power module, the cooling apparatus comprising:
a manifold cover in which a cooling medium flows, the manifold cover including:
an open surface and a closed surface; and
at least one cooling channel portion and at least one rib portion disposed in a longitudinal direction of the cooling apparatus on the closed surface, wherein each cooling channel portion includes at least one first channel opened to one side and at least one second channel opened to another side, and the at least one rib portion is disposed on the closed surface to overlap or extend around each cooling channel portion; and
a fin plate coupled to the open surface of the manifold cover and including:
a cooling portion corresponding to each cooling channel portion, wherein the cooling portion includes a plurality of protrusion portions extending in a direction crossing the at least one first channel and the at least one second channel.

2. The cooling apparatus of claim 1, further comprising:
the power module corresponding to each of the cooling portions of the fin plate.

3. The cooling apparatus of claim 2,
wherein the at least one cooling channel portion of the manifold cover and the cooling portions of the fin plate are disposed in the same number as the power modules.

4. The cooling apparatus of claim 1,
wherein the manifold cover further includes an inlet and an outlet disposed at opposite end portions thereof to allow flow of the cooling medium therethrough, and
wherein the at least one cooling channel portion and the at least one rib portion extend in the longitudinal direction between the inlet and the outlet.

5. The cooling apparatus of claim 1,
wherein a plurality of cooling channel portions are disposed to be spaced apart from each other in the longitudinal direction, and
wherein the at least one rib portion extends in the longitudinal direction to be connected to each cooling channel portion.

6. The cooling apparatus of claim 1,
wherein the at least one cooling channel portion includes:
a plurality of partitions disposed in a direction intersecting the longitudinal direction;
a one-side connection portion connecting first end portions of at least two of the partitions; and
an opposite-side connection portion connecting second end portions of at least two of the partitions, and
wherein the one-side connection portion and the opposite-side connection portion are alternately disposed at each of the partitions.

7. The cooling apparatus of claim 6, wherein the at least one rib portion is disposed in the same number as the partitions.

8. The cooling apparatus of claim 6,
wherein the one-side connection portion is angled toward one side while being connected to the at least two partitions, and
wherein the angled end portion of the one-side connection portion is disposed between rib portions.

9. The cooling apparatus of claim 6,
wherein the opposite-side connection portion is angled toward another side while being connected to the at least two partitions, and
wherein the angled end portion of the one-side connection portion is disposed between rib portions.

10. The cooling apparatus of claim 6,
wherein the at least one first channel and the at least one second channel are defined between respective partitions, and
wherein each of the partitions is inclined relative to the longitudinal direction so that a width of the at least one first channel decreases from the one side to another side, a width of the at least one second channel increases from the one side to another side, and the partitions are alternately inclined in opposite directions.

11. The cooling apparatus of claim 10, wherein among the plurality of partitions, partitions disposed at an outermost sides of the plurality of partitions are connected to edge portions of the manifold cover.

12. The cooling apparatus of claim 1,
wherein the at least one rib portion protrudes from the closed surface of the manifold cover, and
wherein a cross-section of a protruding end portion of the at least one rib portion decreases in a protruding direction of the at least one rib portion.

13. The cooling apparatus of claim 1, wherein an end portion of the at least one rib portion includes a polygonal or curved cross-section.

14. The cooling apparatus of claim 1,
wherein the protrusion portions of the fin plate extend in a direction orthogonal in a direction in which the at least one rib portion extends, and
wherein the protrusion portions are spaced apart from each other in a longitudinal direction of the fin plate.

15. The cooling apparatus of claim 14, wherein the protrusion portions are divided multiple times in an extending direction of the protrusion portions.

16. The cooling apparatus of claim 1, wherein a plurality of cooling channel portions are disposed and the plurality of protrusion portions are divided to cover respective ones of the cooling channel portions.

17. The cooling apparatus of claim 1,
wherein the protrusion portions protrude from the fin plate.

18. The cooling apparatus of claim 17,
wherein a cross-section of protruding end portions of the protrusion portions decreases in a protruding direction of the protrusion portions.

19. The cooling apparatus of claim 1,
wherein a height of the at least one rib portion is lower than a height of the at least one channel portion.
